(19) United States
(12) Patent Application Publication
(10) Pub. No.: US 2019/0343020 A1
(43) Pub. Date: Nov. 7, 2019

(54) COOLING DEVICE WITH INTEGRAL SHIELDING STRUCTURE FOR AN ELECTRONICS MODULE

(71) Applicant: General Electric Company, Schenectady, NY (US)

(72) Inventors: Maja Harfman Todorovic, Niskayuna, NY (US); Philip Michael Cioffi, Schaghticoke, NY (US); Xu She, Cohoes, NY (US); Gary Dwayne Mandrusiak, Latham, NY (US); Rajib Datta, Niskayuna, NY (US); Michael Joseph Schutten, Rotterdam, NY (US)

(21) Appl. No.: 15/968,370

(22) Filed: May 1, 2018

(51) Int. Cl. H05K 7/20; H05K 9/00

(52) U.S. Cl. CPC H05K 7/20272; H05K 7/20927; H05K 1/0209; H05K 9/0015; H05K 9/0022

(57) ABSTRACT

A heat sink for cooling an electronic component includes a substrate comprising an electrically non-conductive material and an inlet port and an outlet port extending outward from the substrate. The inlet and outlet ports are fluidically coupled to a fluid flow surface of the heat sink by passages that extend through a portion of the substrate. The heat sink also includes a shield comprising an electrically conductive material. The shield is disposed atop or within the substrate and is configured to suppress electromagnetic interference generated by an electronic component coupled to the heat sink.

### BACKGROUND OF THE INVENTION

Embodiments of the invention relate generally to cooling devices for electronics modules and, more particularly, to a fluid cooled heat sink having an integral electromagnetic shielding structure.

The electrical system performance of electronic components is limited by the rate at which the heat it produces is removed. In the field of electronics, and power electronics in particular, there is a generally continuous demand for enhanced performance capabilities and increased package density all within a smaller and smaller footprint. These combined demands increase operating temperatures and thereby erode the performance capabilities of the electronic device. Heightened operating temperatures are especially prevalent in power electronics modules since they are designed to operate at increased power levels and generate increased heat flux as a result.

Thermal management of a heat generating component, such as a power electronics module, may be accomplished with a heat sink that enhances heat transfer from the heat generating component and lowers the operating temperature thereof. The heat transfer capabilities of conventional fluid cooled heatsink designs are currently limited by the capabilities of the casting and machining processes used to manufacture them. Large metal heat sinks can also be quite heavy, even when fabricated from relatively light-weight aluminum.

In addition to thermal management, electromagnetic interference (EMI) suppression is an important part of the design of power electronics systems. With the emergence of wide-bandgap power electronics devices, such as SiC and GaN, for example, EMI suppression becomes more critical due to the extremely fast switching speeds of the devices. Therefore, reducing EMI generated during switching events is an important consideration for optimizing performance of power electronics systems.

Therefore, it would be desirable to design an improved electronics packaging solution that suppresses EMI and provides enhanced thermal management for heat generating components such as power devices.

### BRIEF DESCRIPTION OF THE INVENTION

In accordance with one aspect of the invention, a heat sink for cooling an electronic component includes a substrate comprising an electrically non-conductive material and an inlet port and an outlet port extending outward from the substrate. The inlet and outlet ports are fluidically coupled to a fluid flow surface of the heat sink by passages that extend through a portion of the substrate. The heat sink also includes a shield comprising an electrically conductive material. The shield is disposed atop or within the substrate.

In accordance with another aspect of the invention, a method of manufacturing a heat sink for an electronics component includes forming a heat sink substrate from an electrically non-conductive material using an additive manufacturing process, the heat sink substrate comprising a fluid inlet port, a fluid outlet port, and a fluid flow surface fluidically coupled to the fluid inlet port and the fluid outlet port. The method also includes disposing a shield layer on a surface of the heat sink substrate during the additive manufacturing process, the shield layer comprising an electrically conductive material.

In accordance with another aspect of the invention, a thermal management assembly includes a heat sink comprising a substrate comprising an electrically non-conductive material, the substrate having a fluid flow surface fluidically coupled to a fluid inlet port and a fluid outlet port. The heat sink also includes a shielding structure comprising an electrically conductive layer disposed on or within the substrate. A heat generating component is coupled to a mounting surface of the heat sink. The shielding structure suppresses electromagnetic interference generated by the heat generating component.

These and other advantages and features will be more readily understood from the following detailed description of preferred embodiments of the invention that is provided in connection with the accompanying drawings.

### BRIEF DESCRIPTION OF THE DRAWINGS

The drawings illustrate embodiments presently contemplated for carrying out the invention.

In the drawings:

FIG. 1 is a perspective view of a fluid cooled heat sink that includes a shield configured to capture or suppress electromagnetic interference (EMI), according to an embodiment of the invention.

FIG. 2 is a cross-sectional view of the heat sink of FIG. 1.

FIG. 2A is a cross-sectional view of a heat sink according to an alternative embodiment.

FIG. 3 is a cross-sectional view of a fluid cooled heat sink that includes an electromagnetic shield, according to another embodiment of the invention.

FIG. 4 is a cross-sectional view of a fluid cooled heat sink that includes an electromagnetic shield, according to yet another embodiment of the invention.

FIG. 5 is a cross-sectional view of a fluid cooled heat sink that includes an electromagnetic shield, according to yet another embodiment of the invention.

FIG. 6 is a top view of the heat sink of FIG. 1.

FIGS. 6A-6H are detail views of raised surface features that can be incorporated into the heat sink of FIG. 1, according to alternative embodiments of the invention.

FIG. 7 is a top view of a heat sink, according to an alternative embodiment of the invention.

FIG. 8 is a top view of a heat sink, according to an alternative embodiment of the invention.

FIG. 9 is a top view of a heat sink, according to an alternative embodiment of the invention.

FIG. 10 is a bottom view of the heat sink of FIG. 1, according to one embodiment of the invention.

FIG. 11 is a cross-sectional view of a thermal management system that includes the heat sink of FIG. 1, according to an embodiment of the invention.

FIG. 12 is a cross-sectional view of a thermal management system that includes the heat sink of FIG. 4, according to another embodiment of the invention.

FIG. 13 is a perspective view of a multi-module fluid cooled heat sink, according to an embodiment of the invention.

FIG. 14 is a bottom view of the multi-module heat sink of FIG. 13.

FIG. 15 is a cross-sectional view of the multi-module heat sink of FIG. 13.

FIG. 16 is a right side elevational view of the multi-module heat sink of FIG. 13.

FIG. 17 is a left side elevational view of the multi-module heat sink of FIG. 13.

FIG. 18 is a front perspective view of a multi-module fluid cooled heat sink, according to another embodiment of the invention.

FIG. 19 is a rear perspective view of the multi-module heat sink of FIG. 18.

### DETAILED DESCRIPTION

Embodiments of the present invention provide for a cooling device for one or more heat generating components. The cooling device is a fluid cooled heat sink formed as a molded component or using an additive manufacturing technique (e.g., stereolithography or three-dimensional (3D printing) that facilitates forming the heat sink as a unitary structure having a complex geometry of internal fluid passages. The cooling device or heat sink also includes a metallic shielding structure that is configured to suppress or mitigate electromagnetic interference (EMI). The electromagnetic shield is either embedded within the core substrate of the heat sink itself or coupled to a top surface of the core substrate. The electromagnetic shielding fluid cooled heat sink may be designed for attachment to a single heat generating component or module, or may be designed as a multi-module heat sink having a generally planar or three-dimensional geometry, as described in more detail below.

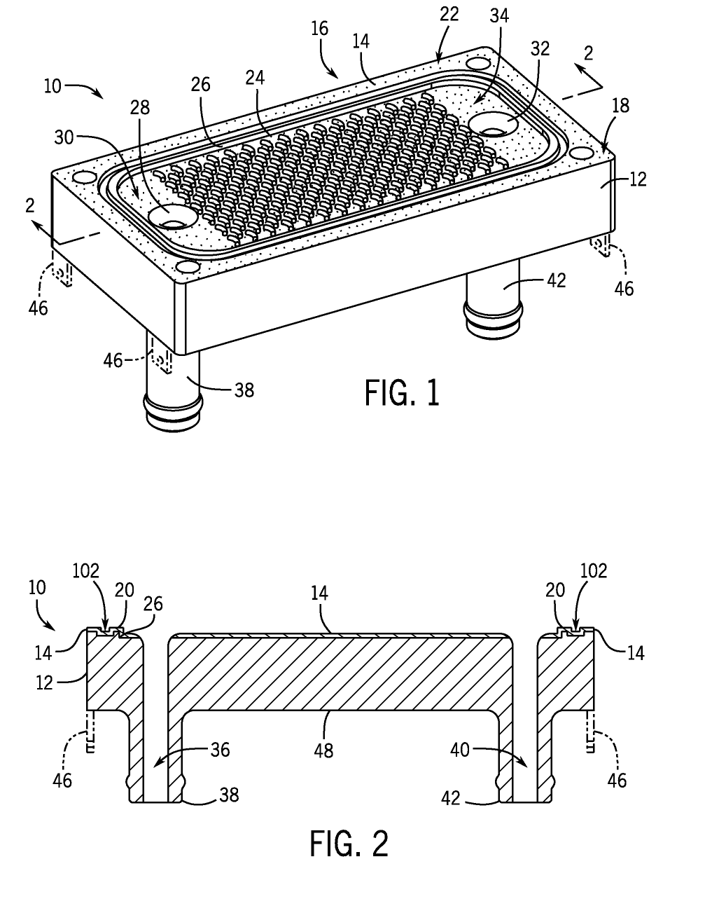

Referring now to FIG. 1, a heat sink 10 is shown according to an embodiment of the invention. Heat sink 10 includes a heat sink substrate 12 and a shielding structure 14 or shield layer configured to capture or suppress electromagnetic interference (EMI). The shield 14 is a conformal structure that is disposed over the top side 16 of the substrate 12. The shield 14 thus defines an exterior surface 18 of the heat sink 10.

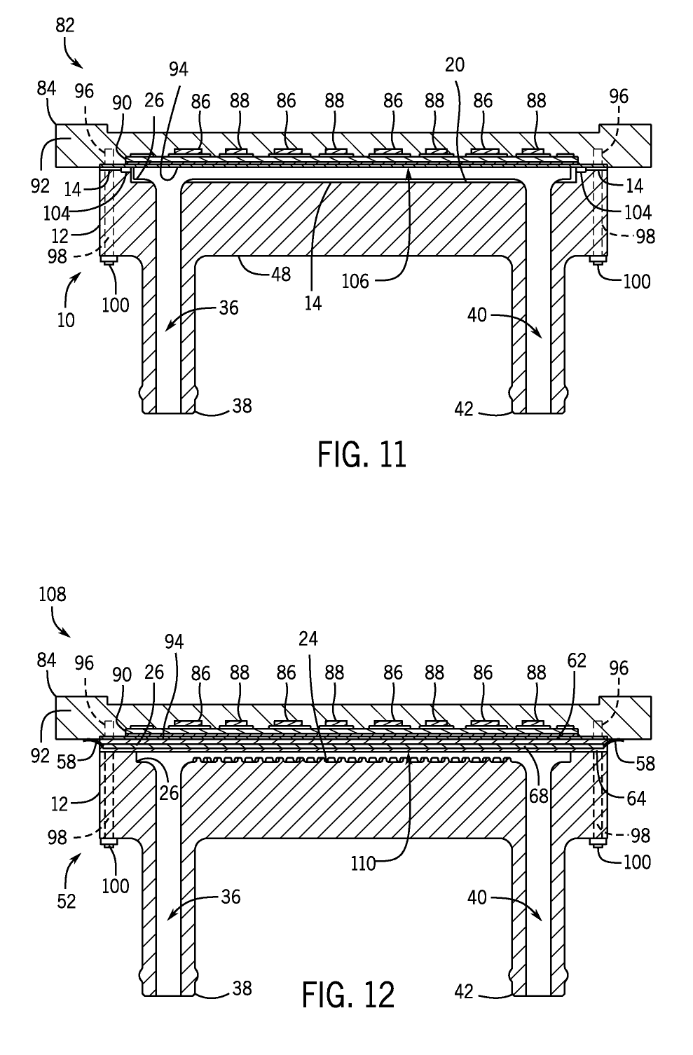

Shield 14 is an electrically conductive material such as copper, silver, nickel, or aluminum nitride as non-limiting examples. Shield 14 may be formed by applying a conductive paint, electroplating, performing a sputtering process, or as part of an additive manufacturing technique such as stereolithography, 3D printing, or other known additive technique. Shield 14 may be a single conductive layer or a stack of conductive layers. In some embodiments, shield 14 includes one or more layers of electrically conductive material (e.g., copper) that define the core structure of shield 14 and an optional barrier layer or plating layer 20 (e.g., titanium, nickel, or an alloy thereof) that is disposed atop the core structure to mitigate corrosion. When heat sink 10 is coupled to a heat generating component such as the power module 84 of FIG. 11, shield 14 functions to shield or capture EMI noise generated by the heat generating component 84.

Shield 14 conforms to the underlying surface topology of the top side 16 of substrate 12, which includes a component mounting surface 22 and a fluid flow surface 24 of the heat sink 10. The fluid flow surface 24 is recessed below the component mounting surface 22 and forms the bottom surface of a recess or well 26 of the heat sink 10. The shield 14 extends across the component mounting surface 22 and extends into the well 26, coating the sidewalls of the well 26 and the fluid flow surface 24. Shield 14 may maintain substantially the same thickness across the top side 16 of substrate 12, or have some areas thinner than others (e.g., on the vertical sidewalls of the well 26).

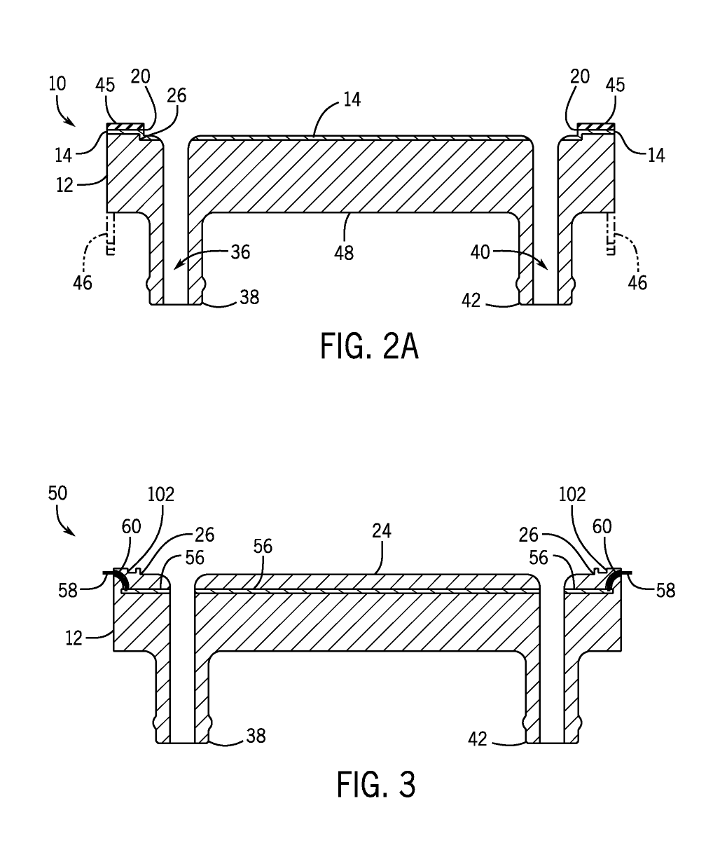

Referring to FIGS. 1 and 10, an inlet orifice 28 is positioned at a first end 30 of the well 26 and an outlet orifice 32 is positioned at a second end 34 of the well 26. Inlet orifice 28 is coupled to a supply passage 36 (FIG. 2) that extends through a portion of the substrate 12 and terminates at a first fluid fitting 38 that functions as a fluid inlet port for receiving a cooling medium. The outlet orifice 32 is coupled to an exhaust passage 40 (FIG. 2) that extends through another portion of the substrate 12. A second fluid fitting 42 is coupled to the exhaust passage 40 and functions as a fluid outlet port for the cooling medium. Thus, cooling medium is permitted to flow across a fluid flow surface 24 in the direction of arrow 44. In some embodiments, shield 14 may extend at least partially into supply passage 36 and/or exhaust passage 40.

In operation, a cooling medium is directed into the inlet fitting 38 and exits from the outlet fitting 42. Inlet fitting 38 and outlet fitting 42 may include coupling devices such as valves, nozzles, and the like, to enable the heat sink 10 to be coupled to inlet and outlet fluid reservoirs (not shown). The cooling medium may be part of a closed loop or open loop system. The cooling medium may be water, an ethylene glycol solution, an alcohol, or any other material having a desirable thermal capacity to remove heat from a heat generating component coupled to the heat sink 10.

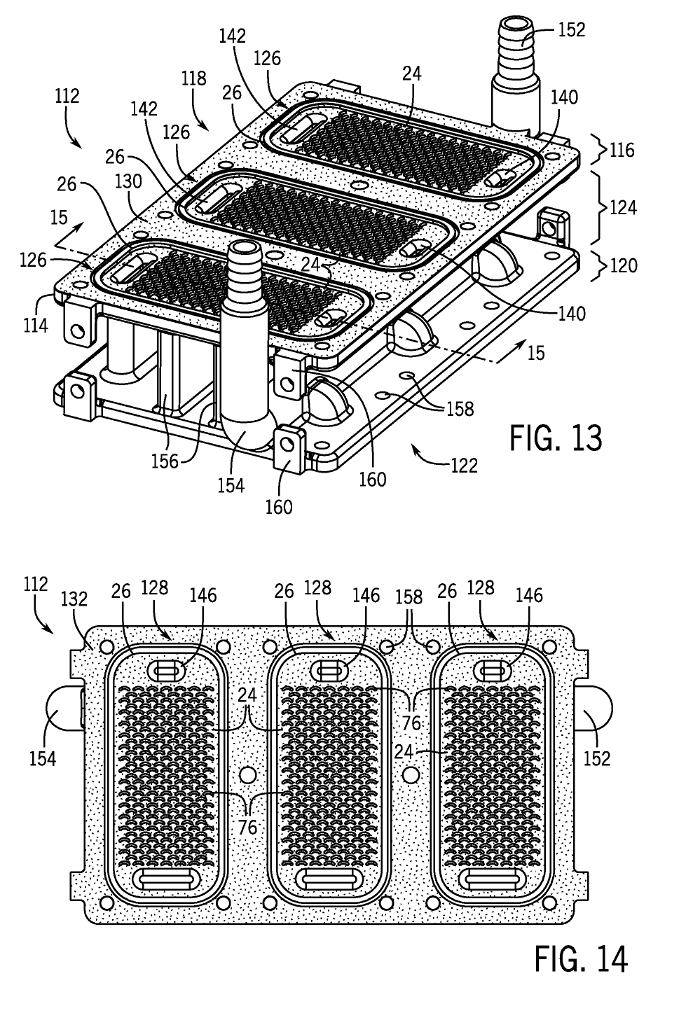

The inlet orifice 28 and outlet orifice 32 may be sized similarly, as shown in FIG. 1, or differ in size according to alternative embodiments (for example as shown in the heat sink design of FIG. 13). Inlet and outlet orifices 28, 32 also may have any cross-sectional shape, including, as non-limiting examples, a generally circular geometry as shown or a slot that extends across a portion of the width of the well 26. The size and shape of the inlet and outlet orifices 28, 32, the inlet and outlet fittings 38, 42, and the supply and exhaust passages 36, 40 are optimized to reduce the total pressure drop within the heat sink 10 and to maintain a uniform flow rate of cooling medium through inlet and outlet fittings 38, 42 and across fluid flow surface 24.

In the illustrated embodiment, the inlet fitting 38 and outlet fitting 42 are arranged generally orthogonal to the fluid flow surface 24. The supply passage 36 defines a generally linear pathway for fluid to flow between the inlet end of the inlet fitting 38 and the inlet orifice 28. Likewise, the exhaust passage 40 defines a generally linear pathway for cooling medium to flow between the outlet orifice 32 and the outlet end of the outlet fitting 42. In alternative embodiments, supply and exhaust passages 36, 40 may define more complex and non-linear passageways through substrate 12 to obtain even fluid flow distribution over the fluid flow surface 24 and minimize pressure loss.

In the illustrated embodiment, the inlet and outlet orifices 28, 32 are generally aligned along the centerline of the well 26 such that the cooling medium is directed across the fluid flow surface 24 in a direction generally perpendicular to the long axis of each of the raised surface features 76. In alternative embodiments, either or both of the inlet and outlet orifices 28, 32 may be positioned off-center (e.g., proximate a corner). In such case the raised surface features 76 may reoriented to be generally orthogonal to the flow direction across fluid flow surface 24.

In one embodiment, substrate 12 and inlet and outlet fittings 38, 42 are formed from an electrically non-conductive material such as a polymer, plastic, ceramic, or composite including fillers and/or additives. Substrate 12 and inlet and outlet fittings 38, 42 may be thermally conductive or thermally non-conductive. In a preferred embodiment, substrate 12 and inlet and outlet fittings 38, 42 are a high-temperature ceramic-plastic composite such as, for example, Accura® Bluestone™, which can handle steady-state operating temperatures (e.g., temperatures at or above 250° C.), has a rigid structure that is able to support limiting machining such as hole drilling and tapping, has sufficient strength to handle high mechanical loadings from hose clamps and nominal fluid pressures during operation. One skilled in the art will recognize that substrate 12 and inlet and outlet fittings 38, 42 are not limited to the listing of materials described herein and that alternative materials may be used to form substrate 12 and inlet and outlet fittings 38, 42 depending on the specific application and design of the heat sink.

The component mounting surface 22 of heat sink 10 may optionally be formed having a recessed groove 102 that surrounds the well 26 and is sized to receive a portion of an O-ring or gasket 104 (shown in FIG. 11). In an alternative embodiment shown in FIG. 2A, the groove and gasket combination is replaced with a layer of compliant or pliable material 45 disposed on the top surface of substrate 12 and sized to surround well 26. This layer of pliable material 45 may be formed during the 3D printing process, using an alternative deposition or printing technique, or coupled to the top side 16 with an adhesive (not shown). When used, pliable material 45 functions similar to gasket 104 to maintain a fluidically-sealed environment between the heat sink 10 a heat generating component coupled thereto.

In some embodiments, heat sink 10 may include one or more additional mounting features 46 (shown in phantom in FIG. 1) to facilitate mounting heat sink 10 to an external assembly (not shown) or for mounting other components (also not shown) to the heat sink 10 itself. Mounting features 46 are illustrated as flanges that project outward from substrate 12 with fastener openings formed within each flange 46. It is contemplated that the geometry of mounting features 46 is not limited to the illustrated flange design and that the particular size, shape, number, and positioning of mounting features 46 may be selected based on that particular application.

Although the heat sink 10 is illustrated having a generally rectangular, box-like shape, embodiments are not limited thereto. For example, the bottom side 48 of the heat sink 10 may be a generally planar surface or have a curved surface topology to facilitate arranging heat sink 10 relative to other external structures. In other embodiments, the top side 16 of heat sink 10 may have a curved surface topology that mirrors a curved mounting surface of a heat generating component.

In a preferred embodiment, substrate 12 and inlet and outlet fittings 38, 42 are manufactured as a unitary structure using an additive manufacturing process such as 3D printing or stereolithography (SLA). Substrate 12 and inlet and outlet fittings 38, 42 may also be manufactured as a unitary structure by a known molding or machining process or a combination of known manufacturing processes including, but not limited to, molding, machining, additive manufacturing, stamping, a known material removal process (e.g., milling, grinding, drilling, boring, etching, eroding, etc.), and/or an additive process (e.g., printing, deposition, etc.). In yet other embodiments, substrate 12 may be formed as a multi-layer structure with inlet and outlet fittings 38, 42 provided as separate components bonded or coupled together by an adhesive, fasteners, or other known joining means.

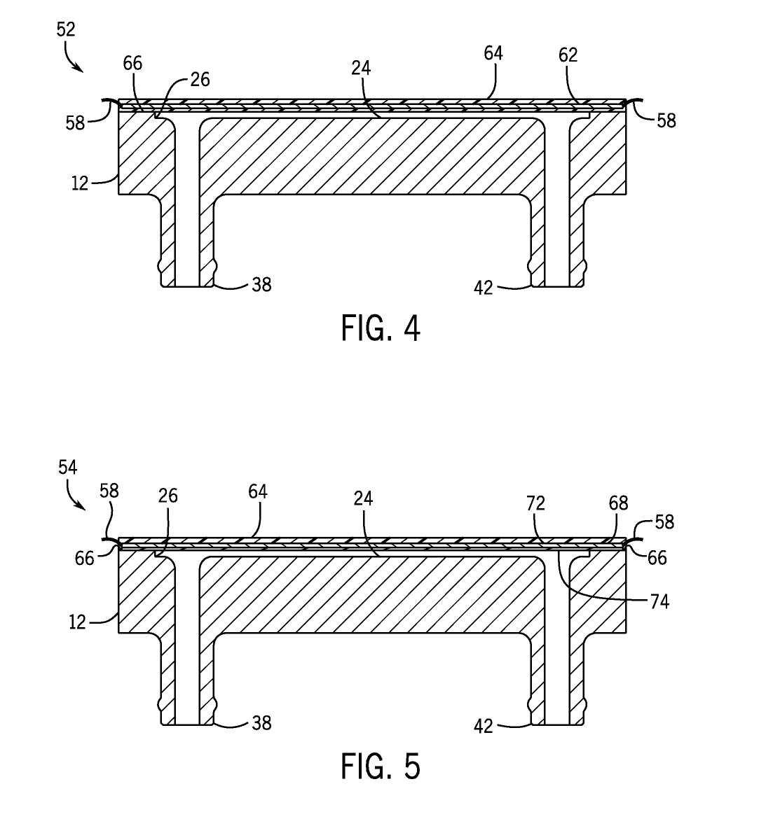

In the embodiment illustrated in FIGS. 1 and 2, the shield 14 is a conformal layer that is formed atop the substrate 12 and thus defines an exterior, mounting surface of the heat sink 10. Alternative heat sink designs may include a shield that is embedded within the substrate 12, embedded within a thermal interface material provided atop the substrate 12, or coupled to a top surface of the substrate 12 and partially surrounded by a thermal interface material, as described in detail below with respect to the heat sink 50 of FIG. 3, heat sink 52 of FIG. 4, and heat sink 54 of FIG. 5. Except for differences in the relative positioning and connections of their respective shields, heat sinks 50, 52, 54 are constructed similarly to heat sink 10 (FIG. 1). Thus, common part numbering is used for similar components as appropriate. By integrating an electromagnetic shield within a heat sink, the embodiments described with respect to FIGS. 1-5 provide cooling and shielding functionality within a common structure.

Referring first to FIG. 3, heat sink 50 is illustrated according to an alternative embodiment that includes a shielding structure 56 that is entirely or substantially surrounded by substrate 12. Shield 56 is a continuous structure with openings formed at the locations of inlet and outlet ports 38, 42. The shield 56 is constructed to enable one or more electrical connections to be made to the shield 56 in order to properly reference the shield for EMI purposes. When the shield 56 is entirely embedded within the substrate 12, this electrical connection is made to the shield 56 by way of one or more wired connections 58 that extend through a passageway 60 formed in substrate 12. Alternatively, wired connection(s) 58 may be replaced by a screw or other type of connector or a portion of the shield 56 may extend entirely outside the substrate 12 or come to an external surface of the substrate 12 thereby facilitating an electrical connection to be made to the shield 56. In yet another embodiment, the electrical connection is made using a Y capacitor. The embedded shield 56 may be a layer of metal formed on an internal surface of the substrate 12 via a deposition or electroplating process carried out as part of the additive manufacturing process. Alternatively, shield 56 may be a thin sheet of metal that is embedded within the substrate 12 during the additive manufacturing process.

FIG. 4 is a cross-sectional view of a heat sink 52 that includes an electromagnetic shielding structure 62 according to an alternative embodiment of the invention. The electromagnetic shield 62 in FIG. 4 is positioned atop substrate 12 and is embedded within one or more TIM layers 64 that are coupled to the mounting surface 66 of the substrate 12 that surrounds well 26. The TIM layer(s) 64 may include, without limitation, adhesives, thermal greases, thermal pastes, films, compliant thermal pads, or the like. In one exemplary embodiment, TIM layer(s) 64 is a mixture of a polymer and a conductive filler material such as an epoxy resin mixed with Al₂O₃ or AlN. A portion of the shield 62 and its surrounding TIM layer(s) 64 is suspended over the well 26. Similar to shielding structures 14, 56 of FIGS. 2 and 3, shielding structure 62 may be a single conductive layer or multiple conductive layers formed from any of the same materials described with respect to shielding structure 14. Shield 62 may be deposited onto an intermediate layer of TIM layer structure 64 using any of the deposition, printing, or plating techniques described above or may be provided as a prefabricated sheet that is embedded within TIM layer 64.

In the embodiment shown in FIG. 5, heat sink 54 includes a shielding structure 68 that is suspended directly over well 26. Shield 68 is provided as a conductive sheet that is bonded to the mounting surface 66 of substrate 12, such as via solder, pressure contact, or other known coupling means. Shield 68 may include any of the same electrically conductive materials described with respect to shield 14 (FIG. 3). As the lower surface of the shield 68 is in direct contact with the cooling medium, shield 68 may be formed as a multi-layer structure composed of a thicker core conductive layer 72 and a plating layer 74 (e.g., nickel) formed on the surface of the shield 68 that faces well 26 to mitigate corrosion. TIM layer 64 covers shield 68.

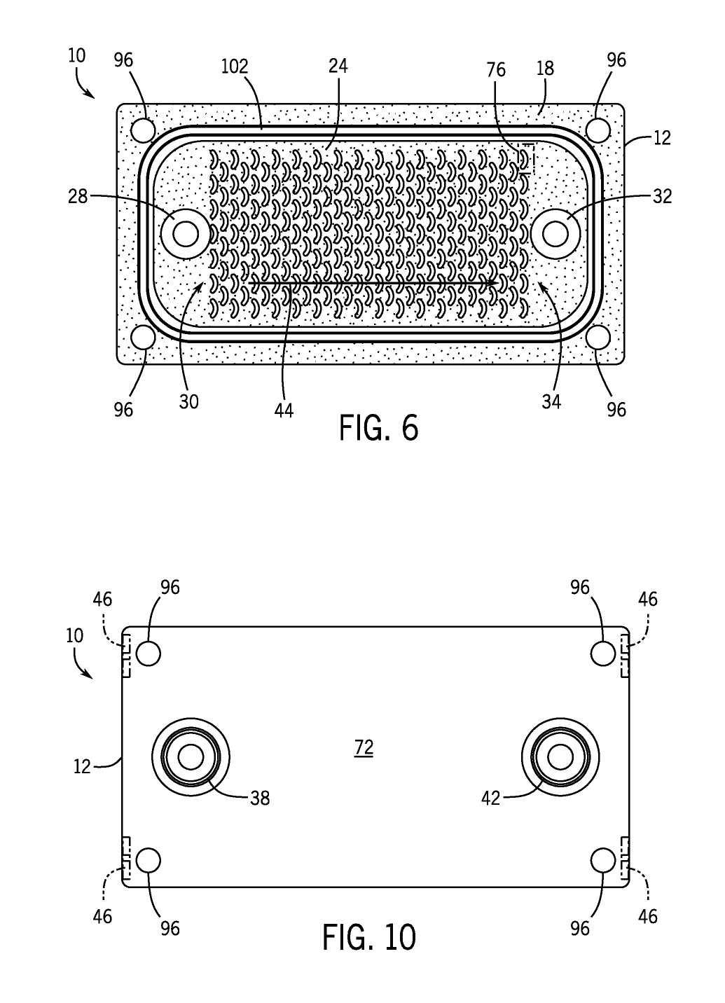

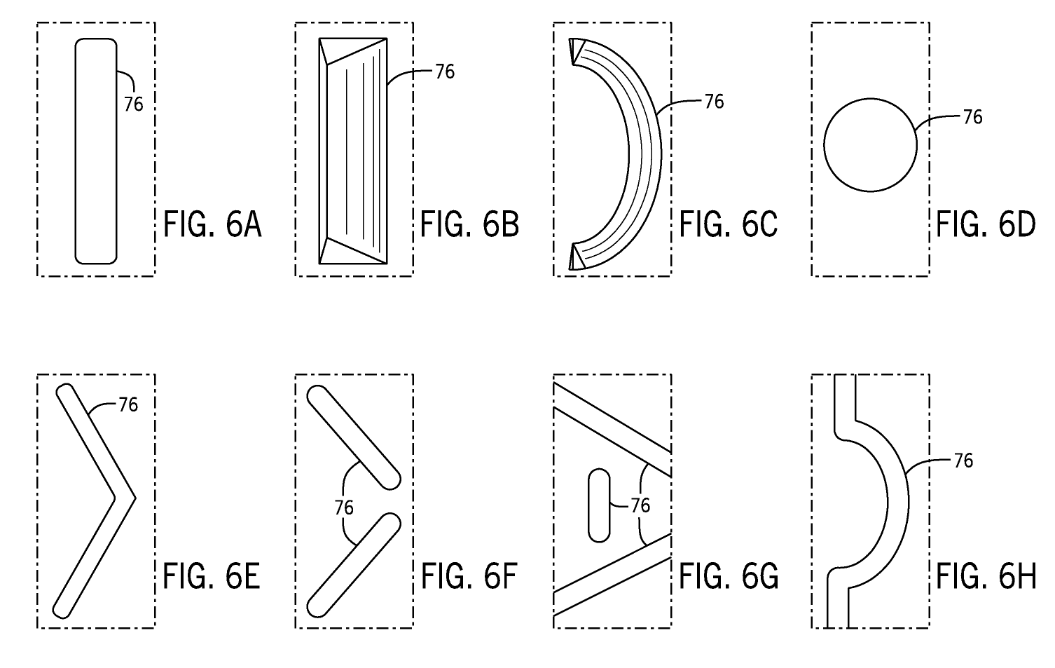

The fluid flow surface 24 of any of the heat sink configurations described with respect to FIGS. 1-5 may include raised surface features that enhance heat transfer away from a heat producing component coupled to the heat sink. Referring now to FIG. 6, embodiments of these raised surface features are described relative to heat sink 10. However, the raised surface features may be similarly included on the fluid flow surface 24 of heat sink 50 (FIG. 3), heat sink 52 (FIG. 4), and heat sink 54 (FIG. 5). In alternative embodiments, raised surface features may be omitted entirely. As shown in FIG. 6, the fluid flow surface 24 of heat sink 10 includes a pattern of surface features 76 located between the fluid inlet 28 and fluid outlet 32. The surface features 76 are raised projections or ridges that extend outward from the fluid flow surface 24 and are configured to disrupt and redirect the flow of the cooling medium as it passes across the fluid flow surface 24. The raised surface features 76 entrain portions of the cooling medium and redirect that cooling medium upward and away from the fluid flow surface 24 in a generally perpendicular direction relative to the arrow 44. These entrained portions of cooling medium form pseudo jets that provide a heat transfer capability comparable to impinging jets with the benefits of reduced cost, reduced surface feature erosion risk, and lower pressure drop.

In the illustrated embodiment, raised surface features 76 are discrete curved, arcuate, or crescent-shaped ridges that are arranged in alternating or offset rows across the fluid flow surface 24. In such an arrangement, cooling medium that passes through a gap formed between two adjacent ridges in one row impinges upon a ridge in the next row. The raised surface features 76 function as ramps to direct coolant upward toward the surface of an adjacent heated component. Additionally, the height and spacing of the raised surface features 76 serve to accelerate and decelerate the flow of cooling medium across the fluid flow surface 24 to further augment the convective coefficient of heat transfer from the adjacent heated surface. The raised surface features 76 thus function to form an array of flow velocity distributed jets (referred hereafter as “pseudo jets”) within the cooling medium flow. These pseudo jets enhance heat transfer between the fluid and an adjacent heated surface, resulting in high local convective coefficients within the immediate zone of impact between the heated surface and a respective pseudo jet.

While the peak local heat transfer coefficients produced by the raised surface features 76 may be comparatively lower than those produced by known impinging jet technologies, the combined effect of the entire array of pseudo jets results in an average convective heat transfer coefficient on an adjacent heated surface that is significantly higher than that produced by the discrete impinging jets of the prior art. A heat sink 10 having the raised surface features 76 also operates at relatively low pressure drop and at channel flow velocities that are well below the threshold normally associated with erosion.

In one exemplary and non-limiting embodiment, the raised surface features 46 are ridges that have a height of approximately 1.0 mm, a width or thickness of approximately 1.0 mm, and a length of approximately 4 mm. In such an embodiment, the well 20 may have a width of approximately 45 mm and a length of approximately 105 mm, with the depth of the well 20 spaced approximately 1.5 mm away from the top surface of the raised surface features 46. The dimensions of the well 20 and the dimensions of the raised surface features 46 may be modified in alternative embodiments to enhance heat transfer based on the design specifications of a particular application.

While illustrated herein as crescent-shaped ridges, it is contemplated that the raised surface features 76 may have numerous other geometries that similarly function to form pseudo jets within the flow of cooling medium. For example, raised surface features 76 may have other curved or arcuate geometries, may be a series of dashed straight line segments, or may have an open waffle pattern formed from a series of bisecting dashed lines. FIGS. 6A-6H, illustrate a number of alternative geometries for raised surface features 76. The raised surface features 76 may be formed as a linear projection (FIG. 6A) or as a linear ramp (FIG. 6B). Raised surface features 76 may also be curved, arcuate, or crescent-shaped ramps similar to that shown in FIG. 6C. Raised surface features 76 may also include a pattern of bumps or dots (FIG. 6D) on the fluid flow surface 24. Alternatively, the raised surface features 76 may be closed v-shaped projections (FIG. 6E), open v-shaped projections (FIG. 6F), a series of angled and straight line segments (FIG. 6G), or a combination of straight and curved line segments (FIG. 6H). In some embodiments, each row of raised surface features 76 within the overall pattern includes multiple, discrete projections similar to that shown in FIG. 6. In alternative embodiments each row of the pattern is formed from a single projection that spans the width of the pattern. The geometric configuration utilized for raised surface features 76 and the overall shape and size of recess 26 may depend on parameters such as flow resistance, the type of cooling medium, and the desired maximum operating temperature of the heat generating component, as non-limiting examples.

In the embodiment illustrated in FIG. 6, the raised surface features 76 have a uniform pattern over fluid flow surface 24. Alternatively, the raised surface features 76 may have a non-uniform or random pattern across the fluid flow surface 24 or form a pattern that is solely concentrated in one or more locations on the fluid flow surface 24 to concentrate flow and enhance heat transfer from one or more local hot spots on the adjacent heated surface of the heat generating component. In yet another embodiment, the raised surface features 46 may form different patterns in different regions on the fluid flow surface 24. For example, the fluid flow surface 24 may be divided into a number of different regions with each region including an array of raised surface features arranged in different patterns. The differing patterns may include different shapes of raised surface features and/or raised surface features arranged with different spacing. For example, a different type of surface feature and/or different inter-feature spacing may be used in regions that will be located under each semiconductor die incorporated within a heat generating component.

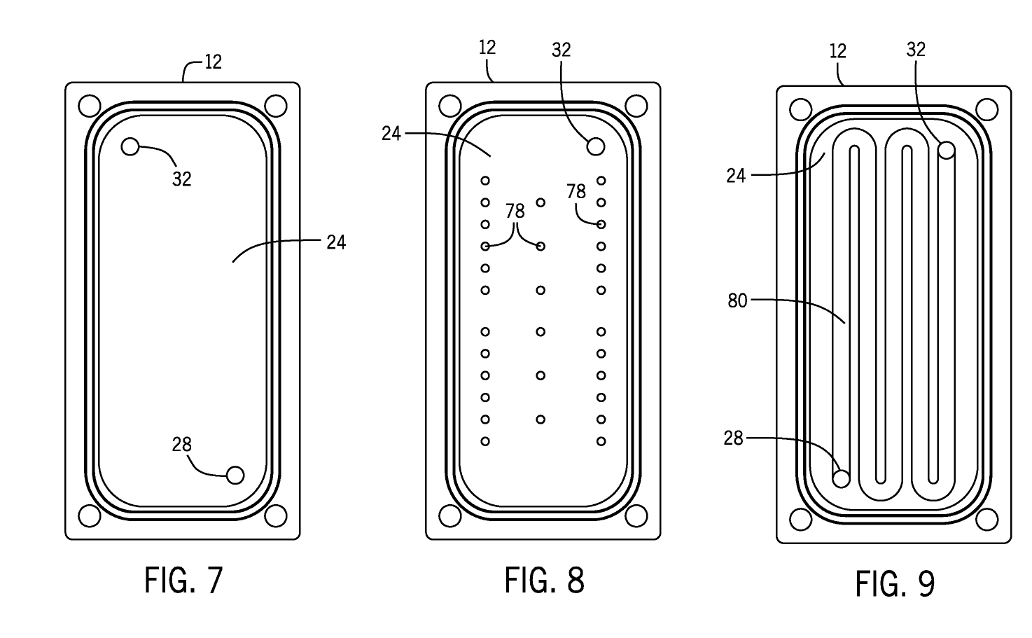

FIGS. 7-9 illustrate three alternative configurations of the fluid flow surface 24 of a heat sink. These alternative configurations that can be implemented into any of the heat sink designs of FIGS. 1-6. In FIG. 7, the fluid flow surface 24 is a planar surface with inlet and outlet orifices 28, 32 positioned across a diagonal from one another. FIG. 8 illustrates an impinging-jet configuration of fluid flow surface 24, where a pattern of jet orifices 78 are formed through the fluid flow surface 24. Cooling medium is directed out of the jet orifices 78, impinges upon an adjacent heated surface, and exits through outlet orifice 32. In yet another alternative embodiment, the fluid flow surface 24 includes a channel 80 that directs cooling medium in a zig-zag pattern between the inlet orifice 28 and the outlet orifice 32. As similarly described with respect to raised surface features 76 of FIG. 6, the size, number, and configuration jet orifices 78 or channel 80 may be modified based on a particular application to enhance heat transfer from a heat generating component. Thus, embodiments of the invention are not limited only to the specifically illustrated fluid flow surface configurations described herein.

Referring now to FIG. 11, a thermal management assembly 82 is illustrated that includes heat sink 10 (FIG. 1) coupled to a heat generating component 84. In one non-limiting embodiment, heat generating component 84 is a power electronics module or package configured for a high-power application, such as an electric motor drive circuit of an electric vehicle or hybrid-electric vehicle. Power electronics module 84 includes an arrangement of semiconductor die 86 and other electronic components 88 coupled to a direct bonded copper substrate 90 and positioned within a housing 92. A copper baseplate 94 forms the bottom surface of the heat generating component 84. Through-hole features or mounting holes 96 extend through the housing 92 and copper baseplate 94. Mounting features 98 included on heat sink 10 are aligned with the mounting holes 96 and fasteners 100 (such as bolts, for example) extend through the aligned mounting features 98 and mounting holes 96 to couple heat sink 10 to the heat generating component 84. One skilled in the art will recognize that power electronics module 84 may include a number of other components including a bus bar, connection terminals, passive components, and electrical interconnections, which have been omitted from the figures for purposes of clarity.

While heat generating component 84 is described herein as a power electronics package, it is understood that heat sink 10 can be configured to facilitate thermal management of any number of alternative types of heat generating components and/or alternative types of electronics packages or components than that described above. Thus, embodiments of the invention are not limited only to the specifically illustrated devices and arrangements thereof. As used herein the term “electrical component” may be understood to encompass various types of semiconductor devices, including without limitation, IGBTs, MOSFETs, power MOSFETs, and diodes, as well as resistors, capacitors, inductors, filters and similar passive devices and/or combinations thereof. In such instances, the position, geometry, spacing, and/or number of surface mounting features 98 may be modified to facilitate mounting the heat sink 10 to the heat generating component 84.

In the embodiment illustrated in FIG. 11, the heat generating component 84 and heat sink 10 are assembled in direct contact with one another, resulting in the formation of a cavity 106 between the copper baseplate 94 of the heat generating component 84 and the portion of the shield 14 located within the well 26. In an alternative embodiment, heat sink 10 may be replaced by heat sink 50 of FIG. 3 in which case the resulting cavity 106 would be formed between the copper baseplate 94 of the heat generating component 84 and fluid flow surface 24 of the substrate 12. In such an embodiment, mounting surface 22 of substrate 12 may include a groove sized to receive gasket 104 or be provided with a layer of compliant or pliable material to facilitate a fluidic seal.

FIG. 12 illustrates a thermal management assembly 108 according to an alternative embodiment that includes the heat sink 52 of FIG. 4 coupled to heat generating component 84. In the illustrated arrangement, heat transfer between the heat generating component 84 and heat sink 10 is accomplished indirectly through TIM layer(s) 64 and the embedded shield 62. The fluid flow surface 24 of heat sink 52 is depicted as including raise surface features 76, which may be omitted in alternative embodiments. Cooling medium flows through a cavity 110 formed between the well 26 and the lower surface of TIM layer(s) 64. In an alternative embodiment, heat sink 52 may be replaced by heat sink 54 (FIG. 5), resulting in cavity 110 being formed between well 26 and the lower surface of the shield 68.

Referring now to FIG. 13, a multi-module heat sink 112 is illustrated according to an embodiment of the invention. Multi-module heat sink 112 is a double-sided heat sink structure formed from a unitary substrate 114. In a preferred embodiment, the unitary substrate 114 is formed from an electrically non-conducting polymer or composite material, such as those described with respect to substrate 12 (FIG. 1) and is formed using an additive manufacturing technique such as 3D printing or stereolithography. In alternative embodiments, and depending on the overall geometry of the substrate 114 and fluid flow passages formed therein, substrate 114 may alternatively be formed using a known molding technique. Multi-module heat sink 112 is illustrated as including raised surface features 76, which may be otherwise configured or omitted entirely in alternative embodiments.

The unitary substrate 114 can be generally described as including three main portions: a first mounting plate portion 116 on the first side 118 of the multi-module heat sink 112, a second mounting plate portion 120 on the second side 122 of the multi-module heat sink 112, and a coolant passage portion 124 positioned between the first and second portions 116, 120. The first mounting plate portion 116 includes three (3) generally co-planar mounting locations 126. Similarly, the second mounting plate portion 120 includes three (3) generally co-planar mounting locations 128. Thus, multi-module heat sink 112 provides discrete mounting locations for six (6) heat generating components in the configuration shown. It is contemplated that heat sink 112 may be modified to provide mounting locations for more or less components than shown herein.

A conformal shielding structure 130, 132 is formed over the outward-facing surfaces of the first and second mounting plate portions 116, 120. Conformal shields 130, 132 may be formed similar to and include any of the same materials as shield 14 of FIG. 1.

In one embodiment the conformal shields 130, 132 may be replaced by shielding structures embedded within the first mounting plate portion 116 and second mounting plate portion 120 in a similar manner as shield 56 of FIG. 3. In yet other alternative embodiments, multi-module heat sink 112 may include TIM layer structures coupled to the outward facing surfaces of first and second mounting plate portions 116, 120, with respective shielding structures either embedded within the TIM layer structure (similar to shield 62 of FIG. 4) or coupled to the respective first or second mounting plate portions 116, 120 and covered by a TIM layer structure (similar to the configuration of TIM layer(s) 64 and shield 68 in FIG. 5).

As best shown in FIGS. 13 and 14, each mounting location 126, 128 includes a well 26, similar to that described with respect to FIGS. 1 and 6, that is recessed within the respective top or outward-facing surfaces of the first and second mounting plate portions 116, 120. In one embodiment, the fluid flow surface 24 includes a pattern of raised surface features 76 having a similar crescent shaped geometry as described with respect to heat sink 10 (FIGS. 1 and 6). However, the size, shape, and overall pattern of raised surface features 76 may be otherwise configured based on any of the alternative configurations described above. In yet other embodiments, the fluid flow surface 24 has one of the surface topologies described with respect to FIGS. 7-9.

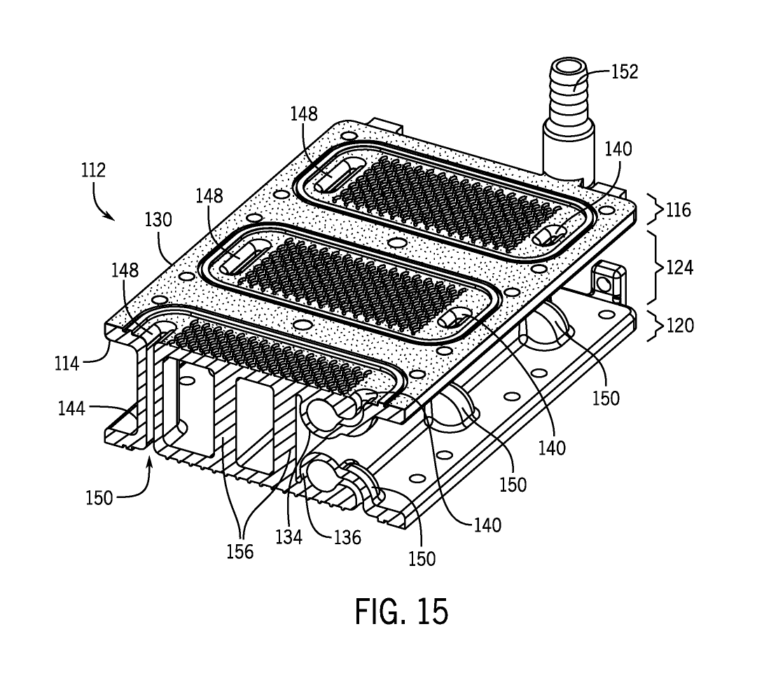

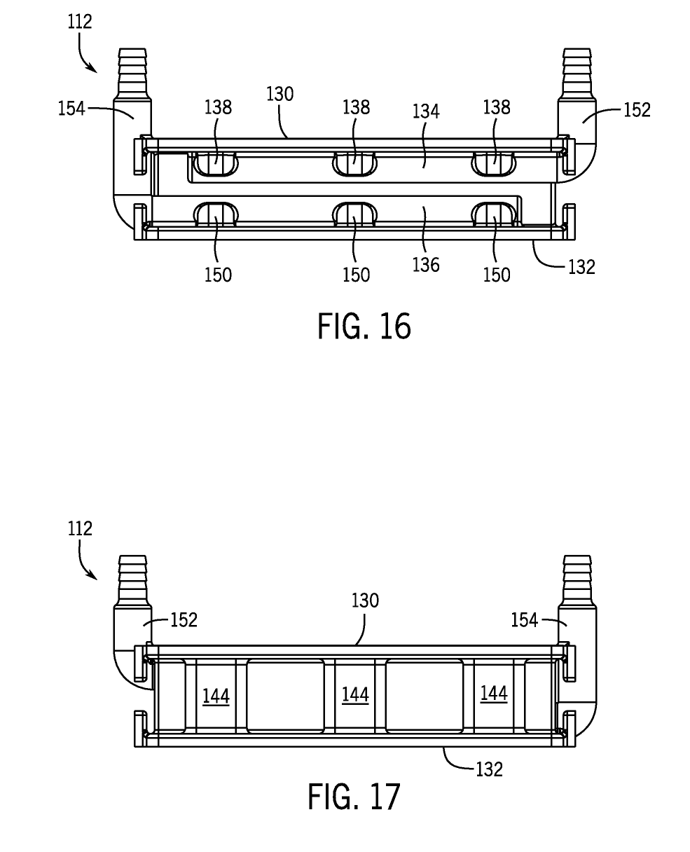

Referring now to FIGS. 15 and 16, the coolant passage portion 124 of multi-module heat sink 112 includes a fluid inlet manifold 134 and a fluid outlet manifold 136 that are formed within substrate 114. A series of inlet branch passages 138 extend off of the fluid inlet manifold 134 and fluidically couple the fluid inlet manifold 134 to the inlet orifices 140 on the first mounting plate portion 116. In operation, cooling medium is directed across the fluid flow surfaces 24 and is directed into outlet orifices 142. Each outlet orifice 142 is coupled to a respective fluid passage 144 that extends through the coolant passage portion 124 of substrate 114 and fluidically couples one of the outlet orifices 142 on the first mounting plate portion 116 to a respective inlet orifice 146 located on the second mounting plate portion 120 opposite the respective outlet orifice 142. Cooling medium is then directed across the fluid flow surfaces 24 located on second mounting plate portion 120 and into respective outlet orifices 148, shown most clearly in FIG. 17. A series of outlet branch passages 150 fluidically couple the outlet orifices 148 to fluid outlet manifold 136.

Cooling medium is directed into the fluid inlet manifold 134 through an inlet fluid fitting 152 and exits multi-module heat sink 112 through an outlet fluid fitting 154 coupled to fluid outlet manifold 136. Inlet and outlet fittings 152, 154 may be located on opposing ends of the multi-module heat sink 112 as shown, on the same end, or in any alternative configuration that facilitates connections to external fluid reservoirs (not shown).

Inlet and outlet orifices 140, 142, 146, 148, inlet branch passages 138, outlet branch passages 150, and fluid inlet and outlet manifolds 134, 136 are sized relative to one another to optimize flow uniformity throughout the coolant passage portion 124. In one embodiment, the inlet orifices 140 on first mounting plate portion 116 are sized larger than the outlet orifices 142 on first mounting plate portion 116, as shown in FIG. 13. The opposite is true on second mounting plate portion 120, with the outlet orifices 148 being formed larger than the inlet orifices 146, as shown in FIG. 14. In one exemplary and non-limiting embodiment, the aforementioned components of coolant passage portion 124 are sized to define an approximate 10:1 ratio in manifold flow area to total branch flow area. However, the relative manifold to branch sizing may have other ratios based on the overall number of mounting locations, the particular parallel and/or series coupling of the mounting locations, the size and geometry of the wells, the overall size and geometry of the substrate 114, the type of cooling medium used, as well as other factors. Thus, it is to be understood that the coolant passage portion 124 is not to be limited to the particular implementations illustrated and described herein would be designed to optimize pressure drop and maintain a reasonably balanced or uniform flow rate of cooling medium through heat sink 112.

As disclosed herein, multi-module heat sink 112 is configured to supply cooling medium in parallel to three pairs of mounting locations 126, 128, with each of those three pairs of mounting locations 126, 128 coupled together in series. However, the coolant passage portion 124 may be designed to define alternative fluid paths and to couple all or select groupings of mounting locations 126, 128 in alternative series and/or parallel arrangements. As one example, all of the mounting locations 126, 128 may be connected in series, with the inlet fitting 152 coupled to the inlet orifice 140 of one of the mounting locations 126 and the outlet fitting 154 coupled to one of the outlet orifices 148. In yet another non-limiting example, all of the inlet orifices 140, 146 may be coupled to a common manifold thereby defining a parallel flow path across all mounting locations 126, 128. In yet other alternative configurations, the coolant passage portion 124 may be designed to provide one or more individual mounting locations 116 with a dedicated fluid inlet passage or include multiple inlet passages, with each passage configured to optimize the fluid flow rate and/or pressure drop for a particular type of heat generating component.

Coolant passage portion 124 also includes one or more support structures 156 that extend between first mounting plate portion 116 and second mounting plate portion 120 and provide structural support for multi-module heat sink 112. In the illustrated embodiment, heat sink 112 includes two structural supports 156 that each span the approximate width of the heat sink 112. It is contemplated that the size, shape, number, and position of structural supports may vary from that shown in alternative multi-module heat sink configurations depending on a number of factors, including the overall heat sink size and geometry, material properties of substrate 114, application, environmental conditions, and the like. In yet other embodiments, support structures 156 may be omitted entirely, with the structural support being provided instead by fluid passageways that extend between the first and second mounting plate portions 116, 120.

Each mounting location 126 includes one or more surface mounting features 158 sized and positioned to facilitate mounting a heat generating component to the multi-module heat sink 112 above the respective mounting location 126. In the embodiment shown, the mounting features 158 are through holes formed through a thickness of the respective mounting plate portion 116, 120. However, it is to be understood that the position, size, shape, and overall geometry of mounting features 158 may be modified to facilitate the mounting of different types of heat generating components. For example, mounting features 158 may be formed as flanges or other types of structures that extend outward from the respective mounting plate portion 116, 120.

Multi-module heat sink 112 may also include one or more additional mounting features 160 (shown in phantom) to facilitate mounting multi-module heat sink 112 to one or more external components. Similar to mounting features 158, external mounting features 160 may be extended structures, such as flanges, or simple through holes formed through a portion of the substrate 114.

While multi-module heat sink 112 is illustrated and described as a unitary two-sided structure, the general concept of a multi-module heat sink described herein may be extend to single-sided multi-module heat sink configurations or multi-module heat sinks formed from two or more individual structures bonded together using known bonding materials and/or techniques. For example, a two-sided multi-module heat sink may be formed from two for a first side of the multi-module heat sink and the second plate including one or more mounting locations for a second side of the multi-module heat sink 112.

In the illustrated embodiment, the mounting locations 126 are configured to cool similar types of heat generating components (e.g., power module 84 of FIG. 11). Thus, the respective mounting locations 126 and wells 26 are commonly sized and include a similar pattern of raised surface features 76 and mounting features 98. In alternative embodiments, the multi-module heat sink 112 different mounting locations configured to optimize cooling of a variety of different types of components. In such case, each mounting location may have a different arrangement of mounting features, a different pattern or type of raised surface features, and/or differ in the size and/or shape of its respective well.

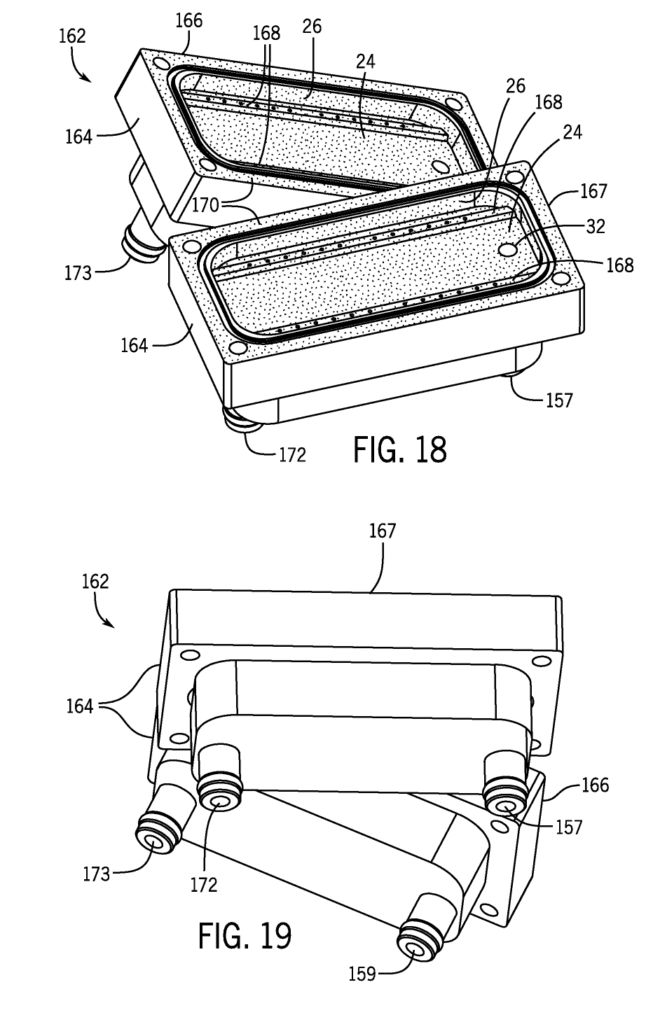

The multi-module heat sink concept may further be extended to heat sink configurations having non-planar fluid flow surfaces. FIGS. 18 and 19, for example, illustrate a non-planar multi-module heat sink 162. Similar to multi-module heat sink 112 (FIG. 13), the core structure of non-planar multi-module heat sink 162 is a unitary substrate 164 that may be formed from any of the electrically non-conductive polymeric or ceramic materials described above. Preferably, substrate 164 is a 3D printed component or is formed using an alternative additive manufacturing process that facilitates creating the complex three-dimensional geometry thereof. In alternative embodiments, heat sink 162 may be assembled from multiple discrete components coupled or bonded to one another to form the desired three-dimensional geometry.

Substrate 164 includes a number of discrete mounting locations 166, 167 formed on outward-facing surfaces of the non-planar multi-module heat sink 162. As shown, the fluid flow surface 24 of mounting location 166 is non-coplanar with the fluid flow surface 24 of mounting location 167. While illustrated as including two discrete mounting locations 166, 167, alternative embodiments of heat sink 162 may include three or more mounting locations with non-coplanar fluid flow surfaces. In the illustrated embodiment, the fluid flow surface 24 at each mounting location 166, 167 includes two raised rows of jet orifices 168 configured for impinging-jet cooling. However, it is contemplated that mounting locations 166, 167 may be configured in a similar manner as the mounting locations 126 described above, and having any of raised surface feature designs described with respect to FIGS. 1 and 6 or any of the alternative fluid flow surface topologies of FIGS. 7-9. The surface topology of the fluid flow surface 24 and the configuration of any raised surface features provided thereon may be the same at all mounting locations 166, 167 or may vary from location to location to optimize heat transfer for different types of heat generating components.

In the illustrated embodiment, multi-module heat sink 162 includes a conformal shielding structure 170 that defines the outward facing surface of each mounting location 166, 167. In alternative embodiments, the conformal shield 170 at each mounting location 166, 167 may be replaced with any of the shielding structure configurations described with respect to FIGS. 3-5.

In the illustrated embodiment, heat sink 162 includes a dedicated fluid inlet passage 172, 173 for each mounting location 166, 167. Fluid inlet passages 172, 173 supply cooling medium in parallel to the rows of jet orifices 168 at each mounting location 166. Cooling medium is directed upward out of the jet orifices 168 and exits the well 20 through a respective outlet orifice 157, 159.

In an alternative embodiment, multi-module heat sink 162 may include a single fluid inlet and a single fluid outlet and an internal fluid passage formed within substrate 164 to fluidically couple the outlet orifice 32 of one of the mounting locations 166, 167 to an inlet orifice of the other mounting location 167, 166. In yet other alternative embodiments, multi-module heat sink 162 may be designed having multiple inlet and outlet manifolds (to couple select subsets of mounting locations 166, 167 in parallel flow arrangements), include dedicated inlet and outlet supplies for some or all of the mounting locations 166, 167, or be configured to define serial flow paths through some or all of the mounting locations 166, 167 of heat sink 162. Similar to that described relative to multi-module heat sink 112, the relative sizing of inlet and outlet orifices, inlet and outlet passages, and inlet and outlet manifold is selected to optimize fluid flow and maintain a desired pressure drop through non-planar multi-module heat sink 162.

Beneficially, embodiments of this invention provide electromagnetic shielding and cooling functionality in a common heat sink structure. The core substrate of the heat sink may be manufactured using an additive manufacturing technique such as 3D printing. The fluid flow surface of the heat sink and the internal fluid flow passages formed therein during the additive manufacturing technique have a relatively complex geometry that enhance heat transfer. Heat transfer is further enhanced in the direct cooling heat sink designs disclosed herein that enable direct contact between the cooling medium and the base plate of the electronics module being cooled. This direct contact eliminates the thermal resistance from thermal interface materials used when coupling a heat sink to an electronics module in prior art constructions. Additionally, the heat sink configurations disclosed herein can be produced at lower cost than conventional aluminum heat sinks, at a comparatively lighter overall weight, and may include structural mounting features that are not supported by conventional heat sink techniques. Accordingly, the embodiments described herein provide a low-cost thermal management and electromagnetic shielding solution with enhanced heat transfer and design flexibility as compared to prior art approaches.

Therefore, according to one embodiment of the invention, a heat sink for cooling an electronic component includes a substrate comprising an electrically non-conductive material and an inlet port and an outlet port extending outward from the substrate. The inlet and outlet ports are fluidically coupled to a fluid flow surface of the heat sink by passages that extend through a portion of the substrate. The heat sink also includes a shield comprising an electrically conductive material. The shield is disposed atop or within the substrate.

According to another embodiment of the invention, a method of manufacturing a heat sink for an electronics component includes forming a heat sink substrate from an electrically non-conductive material using an additive manufacturing process, the heat sink substrate comprising a fluid inlet port, a fluid outlet port, and a fluid flow surface fluidically coupled to the fluid inlet port and the fluid outlet port. The method also includes disposing a shield layer on a surface of the heat sink substrate during the additive manufacturing process, the shield layer comprising an electrically conductive material.

According to yet another embodiment of the invention, a thermal management assembly includes a heat sink comprising a substrate comprising an electrically non-conductive material, the substrate having a fluid flow surface fluidically coupled to a fluid inlet port and a fluid outlet port. The heat sink also includes a shielding structure comprising an electrically conductive layer disposed on or within the substrate. A heat generating component is coupled to a mounting surface of the heat sink. The shielding structure suppresses electromagnetic interference generated by the heat generating component.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A heat sink for cooling an electronic component, the heat sink comprising:
a substrate comprising an electrically non-conductive material;
an inlet port and an outlet port extending outward from the substrate, the inlet and outlet ports fluidically coupled to a fluid flow surface of the heat sink by passages that extend through a portion of the substrate; and
a shield comprising an electrically conductive material, the shield disposed atop or within the substrate.

2. The heat sink of claim 1 wherein the shield comprises an electromagnetic conducting shield that is a conformal structure disposed on the fluid flow surface.

3. The heat sink of claim 2 wherein the shield comprises:
a conductive layer disposed on the fluid flow surface; and
a plating layer disposed on the conductive layer.

4. The heat sink of claim 1 wherein the shield is embedded within the substrate.

5. The heat sink of claim 4 further comprising a wired connection coupled to the shield and extending through a wire passage in the substrate.

6. The heat sink of claim 1 wherein the substrate, the inlet port, and the outlet port comprise a unitary three-dimensionally printed component.

7. The heat sink of claim 1 wherein the fluid flow surface is recessed below a mounting surface of the substrate;
wherein the mounting surface surrounds the fluid flow surface; and
wherein the shield comprises a plate coupled to the mounting surface.

8. The heat sink of claim 1 further comprising a thermal interface material disposed over the shield, wherein a top surface of the thermal interface material defines a mounting surface of the heat sink.

9. The heat sink of claim 8 wherein the shield is embedded within the thermal interface material.

10. The heat sink of claim 1 further comprising a pattern of ridges that extend outward from the fluid flow surface, the pattern of ridges configured to entrain and redirect a flow of fluid across the fluid flow surface.

11. The heat sink of claim 10 wherein the shield comprises a conformal layer that covers the pattern of ridges.

12. A method of manufacturing a heat sink for an electronics component, the method comprising:
forming a heat sink substrate from an electrically non-conductive material, the heat sink substrate comprising a fluid inlet port, a fluid outlet port, and a fluid flow surface fluidically coupled to the fluid inlet port and the fluid outlet port; and
disposing a shield layer on a surface of the heat sink substrate, the shield layer comprising an electrically conductive material.

13. The method of claim 12 further comprising disposing the shield layer on an internal surface of the heat sink such that the shield layer is embedded within the heat sink substrate.

14. The method of claim 12 further comprising disposing the shield layer on the fluid flow surface of the heat sink substrate.

15. The method of claim 12 further comprising forming the shield layer using one of a metal deposition process and an electroplating process.

16. The method of claim 12 wherein disposing the shield layer comprises coupling a metal sheet to a mounting surface of the heat sink substrate that surrounds the fluid flow surface.

17. The method of claim 12 further comprising disposing the shield layer within at least one thermal interface layer coupled to mounting surface of the heat sink substrate that surrounds the fluid flow surface.

18. The method of claim 12 further comprising forming the fluid flow surface having one of a pattern of raised surface features, a plurality of jet orifices, and a fluid flow channel.

19. A thermal management assembly comprising:
a heat sink comprising:
a substrate comprising an electrically non-conductive material, the substrate having a fluid flow surface fluidically coupled to a fluid inlet port and a fluid outlet port; and
a shielding structure comprising an electrically conductive layer disposed on or within the substrate; and
a heat generating component coupled to a mounting surface of the heat sink;
wherein the shielding structure suppresses electromagnetic interference generated by the heat generating component.

20. The thermal management assembly of claim 19 wherein the mounting surface comprises a surface of the substrate that surrounds the fluid flow surface; and
wherein the shielding structure comprises a conformal layer that covers the mounting surface and the fluid flow surface.

21. The thermal management assembly of claim 19 wherein the shielding structure is embedded within the substrate.

22. The thermal management assembly of claim 19 wherein the heat sink further comprises a thermal interface layer having a first surface coupled to the substrate and a second surface that defines the mounting surface of the heat sink.

23. The thermal management assembly of claim 22 wherein the shielding structure is positioned between the second surface of the thermal interface layer and the fluid flow surface of the substrate.
